(19) United States
(12) Patent Application Publication
(10) Pub. No.: US 2024/0170611 A1
(43) Pub. Date: May 23, 2024

(54) OPTOELECTRONIC SEMICONDUCTOR CHIP, MANUFACTURING METHOD AND SEMICONDUCTOR COMPONENT

(71) Applicant: ams-OSRAM International GmbH, Regensburg (DE)

(72) Inventors: Korbinian Perzlmaier, Regensburg (DE); Alexander Pfeuffer, Regensburg (DE); Christian Eichinger, Wenzenbach (DE); Andreas Leber, Regensburg (DE)

(21) Appl. No.: 18/551,780

(22) PCT Filed: Mar. 11, 2022
(86) PCT No.: PCT/EP2022/056324

§ 371 Date: Sep. 21, 2023

(30) Foreign Application Priority Data
Mar. 25, 2021 (DE) 10 2021 202 920.5

(51) Int. Cl. H01L 33/20; H01L 25/075; H01L 33/36; H01L 33/44

(52) U.S. Cl. CPC H01L 33/20; H01L 25/0753; H01L 33/36; H01L 33/44; H01L 2933/0016; H01L 2933/0025

(57) ABSTRACT

In an embodiment an optoelectronic semiconductor chip includes a semiconductor layer sequence with a bottom side, a bottom coating located on the bottom side and an electrode layer located on an underside of the bottom coating facing away from the semiconductor layer sequence, wherein the bottom coating has a thickness gradient and at least one ridge line at which the bottom coating is thickest, wherein the electrode layer extends over the at least one ridge line such that a contact side of the electrode layer facing away from the semiconductor layer sequence follows the bottom coating true to shape, and wherein an electrical and mechanical contact plane of the contact side parallel to the bottom side is defined by the at least one ridge line.

### CROSS-REFERENCE TO RELATED APPLICATIONS

This patent application is a national phase filing under section 371 of PCT/EP2022/056324, filed Mar. 11, 2022, which claims the priority of German patent application 10 2021 202 920.5, filed Mar. 25, 2021, each of which is incorporated herein by reference in its entirety.

### TECHNICAL FIELD

An optoelectronic semiconductor chip is disclosed. In addition, a manufacturing method for such semiconductor chips and a semiconductor component having such semiconductor chips are disclosed.

### SUMMARY

Embodiments provide an optoelectronic semiconductor chip that can be assembled efficiently and precisely.

According to at least one embodiment, the semiconductor chip comprises a semiconductor layer sequence having a bottom side. The bottom side may be planar and flat. In particular, the bottom side faces an emission side on which at least a predominant part of the radiation generated in the semiconductor layer sequence is emitted. The bottom side is, for example, a main side, i.e. a largest side, of the semiconductor layer sequence.

The semiconductor layer sequence comprises at least one active zone that is configured to generate or detect radiation during operation of the semiconductor chip. If the semiconductor chip is configured to generate radiation, the generated radiation is preferably incoherent and is in particular visible light such as blue light, green light and/or red light. The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs or such as AlₙGaₘIn₁₋ₙ₋ₘAsₖP₁₋ₖ, where in each case 0≤n≤1, 0≤m≤1 and n+m≤1 as well as 0≤k<1. For example, 0<n≤0.8, 0.4≤m<1 and n+m≤0.95 as well as 0<k≤0.5 applies to at least one layer or to all layers of the semiconductor layer sequence. In this context, the semiconductor layer sequence may comprise dopants as well as additional components. For the sake of simplicity, however, only the essential constituents of the crystal lattice of the semiconductor layer sequence, i.e. Al, As, Ga, In, N or P, are given, even if these may be partially replaced and/or supplemented by small amounts of additional substances.

According to at least one embodiment, the semiconductor chip comprises a bottom coating on the bottom side. The bottom coating may be formed by a single material or is composed of multiple components or layers. Preferably, the bottom coating is at least partially electrically conductive. In the latter case, the bottom coating comprises, for example, a transparent conductive oxide, TCO for short, such as ITO or zinc oxide, or at least one metal such as Al, Ag and/or Au.

According to at least one embodiment, the semiconductor chip comprises an electrode layer on an underside of the bottom coating facing away from the semiconductor layer sequence. The electrode layer may be located directly at the underside. The electrode layer is preferably a metallic layer and comprises, for example, Al, Ag and/or Au. For example for corrosion protection or contact improvement, the electrode layer may be provided with at least one coating, for example TiW or TiWN.

According to at least one embodiment, the bottom coating has a thickness gradient. That is, a thickness of the bottom coating varies across the bottom coating.

According to at least one embodiment, the bottom coating comprises one or more ridge lines. The at least one ridge line is located in particular at a point where the bottom coating is thickest. For example, the ridge line is shaped similar to a ridge.

According to at least one embodiment, the electrode layer extends across the at least one ridge line. That is, the at least one ridge line is not a tear-off line for the electrode layer, but the electrode layer preferably enables an electrically conductive connection across the at least one ridge line.

According to at least one embodiment, an electrical contact side of the electrode layer facing away from the semiconductor layer sequence follows the bottom coating true to shape. In other words, the contact side may have the same shape as the bottom coating when viewed in cross-section. This applies, for example, with a tolerance of at most 50% or 25% or 10% of a maximum thickness of the bottom coating.

According to at least one embodiment, the at least one ridge line defines an electrical and mechanical contact plane of the contact side parallel to the bottom side. In other words, the ridge line followed by the electrode layer true to shape ensures that the semiconductor chip can be mounted in a controlled orientation. In this case, the bottom side is aligned parallel to a carrier mounting side of a carrier on which the semiconductor chip is mounted.

In at least one embodiment, the optoelectronic semiconductor chip comprises a semiconductor layer sequence having a bottom side. A bottom coating is provided on the bottom side. An electrode layer is disposed on a bottom side of the bottom coating facing away from the semiconductor layer sequence. The bottom coating has a thickness gradient and at least one ridge line where the bottom coating is thickest. The electrode layer extends over the at least one ridge line so that a contact side of the electrode layer facing away from the semiconductor layer sequence conforms the bottom coating to the shape. The at least one ridge line defines an electrical and mechanical contact plane of the contact side parallel to the bottom side.

In particular, a contact pad on the underside with, for example, a ring-shaped deposition structure is described in order to be able to establish an improved mechanical and electrical connection. This applies in particular to LED chips, sensor chips and so-called μLED chips, which have small lateral dimensions. The principle described here can be applied to all types of connection of a semiconductor chip to a carrier, but in particular to bonded semiconductor chips.

Thus, the semiconductor chip can be both an emitter and a sensor. In particular, the semiconductor chip is intended for installation in a display. The semiconductor chip can be used especially in applications that benefit from a defined emission direction of the semiconductor chip.

Precisely aligning the emission directions of semiconductor chips, such as LEDs, sensors or μLEDs, relative to each other can be comparatively challenging, especially in cases of directly viewed displays where as identical as possible emission patterns are required for all LEDs or μLEDs, both within an RGB pixel and between pixels. In addition, the special contact pad structure described here is particularly advantageous when an adhesive, such as an electrically non-conductive adhesive, is used to mechanically attach the semiconductor chips in order to achieve high performance of the overall system.

Semiconductor chips with flat contact pads, on the other hand, tend to tilt slightly during bonding. This can be prevented with the contact structure described here, for example by providing the semiconductor chips with a contact edge that is annular in plan view so that an electrical contact can be better defined through a non-conductive, dielectric adhesive. In particular, the contact edge can penetrate the adhesive more easily. At the same time, such a ring structure will allow the orientation of the semiconductor chip to be precisely defined, since a contact surface can be precisely adjusted. In other words, tilting of the semiconductor chip during an assembly can be avoided.

According to at least one embodiment, the bottom coating has exactly one ridge line. Preferably, the ridge line is a closed line. Alternatively, the ridge line may be an open line, i.e., the ridge line may have two ends, or in the case of a branched ridge line, more than two ends.

According to at least one embodiment, the ridge line or at least one of the ridge lines is a circle, seen in plan view on the bottom side. As an alternative to a circle, the relevant ridge line may also be designed as an ellipse, as a rectangle, as a polygon or as an are triangle, as seen in plan view. If there are several ridge lines, these can be arranged concentrically around each other.

According to at least one embodiment, the bottom coating comprises one or more base bodies. The at least one base body is preferably located directly on the bottom side.

According to at least one embodiment, the bottom coating comprises one or more step layers. The at least one step layer is located in particular directly on a valley side of the base body facing away from the semiconductor layer sequence.

According to at least one embodiment, the valley side is free of the step layer in a central region. This means that the step layer then only partially covers the base body, in particular only at an outer edge.

According to at least one embodiment, the step layer runs around the central region, in particular in a closed line. In this case, the at least one ridge line is preferably defined by the at least one step layer. In particular, the ridge line is where the step line ends towards the central region and/or slopes or tapers off towards the central region with a step.

According to at least one embodiment, the ridge line or at least one of the ridge lines bounds the central region. It is possible that the entire central region of the bottom coating is closer to the bottom side of the semiconductor layer sequence than the ridge line. That is, the valley side may be located within a crater-like structure framed by the ridge line. Thus, the corresponding at least one ridge line overhangs the central region in the direction away from the semiconductor layer sequence.

According to at least one embodiment, the central region constitutes at least 5% or at least 10% or at least 20% or at least 40% or at least 70% of the bottom side, as seen in plan view of the bottom side. That is, the ridge line may frame or encircle a comparatively large area. It is additionally possible for the central region to comprise at most 90% or at most 75% of the bottom side.

According to at least one embodiment, the at least one base body is made of an electrically conductive material. In particular, the base body is metallic and made, for example, of Ag or Al or Au. Alternatively, the base body is made of a TCO. Preferably, the base body is made of exactly one material, but can alternatively be composed of several materials.

According to at least one embodiment, the at least one step layer is made of a dielectric material, for example at least one oxide such as aluminum oxide and/or silicon oxide. Alternatively, the step layer is made of an electrically conductive material, such as a TCO, or is a metallic layer. The stepped layer may be composed of a plurality of sub-layers. For example, the step layer is then a mirror layer and/or a barrier layer against moisture penetration.

According to at least one embodiment, the at least one step layer has a constant, uniform layer thickness in areas where it is present. This means that the stepped layer is applied to the base body without any specific variation in thickness.

According to at least one embodiment, the layer thickness of the stepped layer is at least 20 nm or at least 50 nm. Alternatively or additionally, the layer thickness is at most 3 μm or at most 0.5 μm or at most 0.2 μm or at most 100 nm. This means that the stepped layer can be relatively thin.

According to at least one embodiment, the bottom coating has a maximum thickness of at least 50 nm or of at least 100 nm. Alternatively or additionally, the maximum thickness is at most 3 μm or at most 1.0 μm or at most 0.7 μm or at most 0.5 μm or at most 0.3 μm.

According to at least one embodiment, the base body is convexly curved throughout. This means that, viewed in cross-section, the base body can be shaped like a converging lens. A maximum thickness of the base body is preferably present in the central region.

According to at least one embodiment, the bottom coating, as seen in cross-section, is curved only in an edge region and is otherwise oriented parallel or approximately parallel to the bottom side. The stepped layer may be limited to the edge region.

According to at least one embodiment, the electrode layer completely covers the bottom coating. Alternatively, the electrode layer covers the bottom coating only partially.

According to at least one embodiment, the semiconductor chip is a PLED. This means, for example, that an edge length of the bottom side as seen in plan view is at least 1 μm or at least 3 μm and/or at most 0.2 mm or at most 100 μm or at most 30 μm or at most 20 μm or at most 10 μm. For example, the edge length is between 1 μm and 10 μm inclusive.

According to at least one embodiment, the bottom coating has a monotonically or strictly monotonically decreasing thickness, starting from the at least one ridge line, in the direction towards the edges of the bottom side. In this regard, it is possible that the bottom coating extends to the edges or close to the edges, as seen in plan view of the bottom side. Likewise, the bottom coating may extend to at least one side surface of the semiconductor layer sequence, i.e., it may extend beyond the edges. Close to the edges means, for example, that a distance from the bottom coating to the associated edge is at most 2 m or at most 1 μm or at most 500 nm or at most 100 nm.

According to at least one embodiment, the electrode layer has a constant thickness, in particular in the central region. A local thickness is in particular at a specific point of the electrode layer a smallest distance between two opposite main sides of the electrode layer, preferably one of these main sides being the contact side. It is also possible for the thickness of the electrode layer to decrease towards its edges, so that the electrode layer can taper out thinly and have a decreasing thickness at the edges.

According to at least one embodiment, the semiconductor chips are provided for electrical contact on both sides. That is, a first electrical contact is made via the bottom side and a second electrical contact is made via the emission side. Alternatively, the semiconductor chips may be flip chips.

In the case of flip chips, the contact plane can be laid through the highest points of the two electrical contacts on the bottom side, i.e. both ridge lines define planes for themselves which need not coincide with the jointly defined plane, for example because the optoelectronic semiconductor chip is bent through and the two electrical contacts are tilted relative to each other. Thus, the optoelectronic semiconductor chip would then rest, for example, on the ridge lines of the outer sides of the corresponding electrical contacts.

In addition, a method of manufacturing a semiconductor chip as described in connection with one or more of the above embodiments is disclosed. Features of the semiconductor chip are therefore also disclosed for the method and vice versa.

In at least one embodiment, the method is used to produce at least one optoelectronic semiconductor chip and comprises the following steps, in particular in the order indicated:
A) Providing the semiconductor layer sequence, wherein the semiconductor layer sequence is preferably already singulated and can have essentially the dimensions of the later semiconductor chip,
B) applying the bottom coating to the bottom side,
C) forming the at least one ridge line, in particular by removing material and/or by applying the step layer and optionally structuring the step layer, and
D) providing the electrode layer by overmolding the bottom coating true to shape with a material of the electrode layer.

In addition, a semiconductor component having at least one semiconductor chip as described in connection with one or more of the above embodiments is disclosed. Features of the semiconductor chip are therefore also disclosed for the semiconductor component, and vice versa.

In at least one embodiment, the semiconductor component comprises one or more optoelectronic semiconductor chips as well as a carrier and a connecting means, which is for example a solder or an adhesive. The optoelectronic semiconductor chips are attached to a preferably planar carrier mounting side of the carrier by the connecting means, with the bottom sides preferably oriented parallel to the carrier mounting side. The electrode layers are pressed in the region of the ridge lines by the connecting means up to the carrier mounting side, so that orientations of the bottom sides are defined by the ridge lines. For example, the bottom sides are all oriented parallel to each other due to the ridge lines of the individual semiconductor chips.

According to at least one embodiment, the semiconductor component is a red-green-blue display. For example, the semiconductor component then comprises at least 103 or at least 105 or at least 107 of the optoelectronic semiconductor chips.

In the following, an optoelectronic semiconductor chip described herein, a method described herein and a semiconductor component described herein are explained in more detail with reference to the drawing on the basis of embodiment examples. Identical reference signs indicate identical elements in the individual figures. However, no references to scale are shown, rather individual elements may be shown exaggeratedly large for better understanding.

### BRIEF DESCRIPTION OF THE DRAWINGS

The drawings show:

FIGS. 1 to 4 schematic sectional views of process steps of an embodiment of a manufacturing process for optoelectronic semiconductor chips described herein;

FIGS. 5 to 8 schematic sectional views of process steps of an embodiment of a manufacturing process for optoelectronic semiconductor chips described herein;

FIG. 9 a schematic sectional view of a region around a ridge line of an embodiment of an optoelectronic semiconductor chip described herein;

FIGS. 10 to 13 schematic top views of embodiments of semiconductor optoelectronic chips described herein;

FIGS. 14 to 17 schematic sectional views of embodiments of semiconductor optoelectronic chips described herein; and

FIG. 18 a schematic sectional view of an embodiment of a semiconductor component with optoelectronic semiconductor chips described herein.

### DETAILED DESCRIPTION OF ILLUSTRATIVE EMBODIMENTS

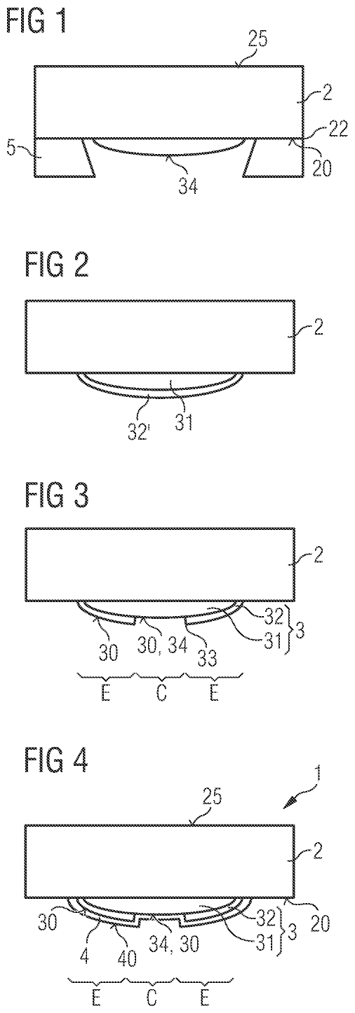

FIGS. 1 to 4 show an embodiment of a manufacturing method for optoelectronic semiconductor chips 1. According to FIG. 1, a semiconductor layer sequence 2 is provided. The semiconductor layer sequence 2 is based, for example, on the material system AlInGaN. The semiconductor layer sequence 2 is preferably already separated from a wafer, but can alternatively still be a part of a wafer, so that a separation can take place only in a subsequent, not shown process step, for example only after the step of FIG. 4.

It is also illustrated in FIG. 1 that a base body 31 of a bottom coating 3 is applied to a bottom side 20 of the semiconductor layer sequence 2. The bottom side 20 is opposite an emission side 25 of the semiconductor layer sequence 2. The bottom side 22 is flat, for example. The base body 31 does not extend to edges 22 of the bottom side 22. Further, the base body 31 is lens-shaped, for example spherical segment-shaped. A maximum thickness of the base body 31 is, for example, between 0.1 μm and 0.3 μm inclusive. A valley side 34 of the base body 31 facing away from the semiconductor layer sequence 2 can thus be continuously curved.

The shape of the base body 31 can be adjusted, for example, with a mask layer 5 which overhangs towards the base body 31 and which has a greater thickness than the base body 31. The curved shape of the valley side 34 results, in particular, from shading effects on the mask layer 5 when a material of the base body 31 is applied. The base body 31 is, for example, made of Ag, Al or Au which is vapor-deposited.

According to FIG. 2, a base layer 32′ for a step layer 32 is applied to the base body 31. The starting layer 32′ is preferably applied true to shape to the valley side 34 of the base body 31 so that the starting layer 32′ has the same cross-sectional shape as the base body 31, merely enlarged and/or displaced. The same masking layer 5 can be used to produce the starting layer 32′ as for the base body 31.

The starting layer 32′ is preferably thin, for example with a thickness of at least 20 nm and/or of at most 100 nm. For example, the starting layer 32′ is made of a dielectric material such as silicon dioxide and/or aluminum oxide.

In FIGS. 1 and 2, the starting layer 32′ and the base body 31 are each formed by only a single material. Starting layers 32′ and base bodies 31 composed of several sublayers and/or materials are also possible, as in all other embodiment examples.

According to FIG. 3, the starting layer 32′ is patterned to form a step layer 32, for example with the aid of a further mask layer, not shown. This exposes the valley side 34 in a central region C. In a circumferential edge region E, the step layer 32 remains and completely covers the base body 31 there. A bottom coating 3 is thus composed of the step layer 32 and the base body 31.

Removal of the step layer 32 from the central region C results in a thickest portion of the bottom coating 3 along an edge of the exposed central region C. This thickest portion forms a ridge line 33. The step layer 32 ends toward the central region 33 at or near the ridge line 33.

According to FIG. 4, an electrode layer 4 is applied to the bottom coating 2. The electrode layer 4 is preferably a metallic layer, for example of Ag, Al and/or Au. A thickness of the electrode layer 4 is, for example, at least 30 nm or at least 50 nm and/or at most 0.25 μm or at most 120 nm.

The electrode layer 4 overmolds the bottom coating 2 true to shape, so that a contact side 40 of the electrode layer 4 facing away from the semiconductor layer sequence 2 has the same shape or basic shape as the bottom side 30 of the bottom coating 3. In this case, the electrode layer 4 is preferably a continuous, uninterrupted layer that overmolds the ridge line 33 without tearing.

At least within the ridge line 33, the electrode layer 4 has a constant layer thickness, for example, whereby the electrode layer 4 can extend with constant thickness over the ridge line 33. It is possible that the electrode layer 4 becomes thinner towards outer edges of the bottom coating 3 and thus tapers off.

The resulting optoelectronic semiconductor chip 1 is in particular a PLED. That is, the semiconductor chip 1 is arranged to generate light and the bottom side 20 has an edge length or an average edge length between 1 μm and 30 μm inclusive. A thickness of the semiconductor layer sequence 2 perpendicular to the bottom side 20 is, for example, between 0.5 μm and 5 μm inclusive, in particular between 1.0 μm and 2.5 μm inclusive.

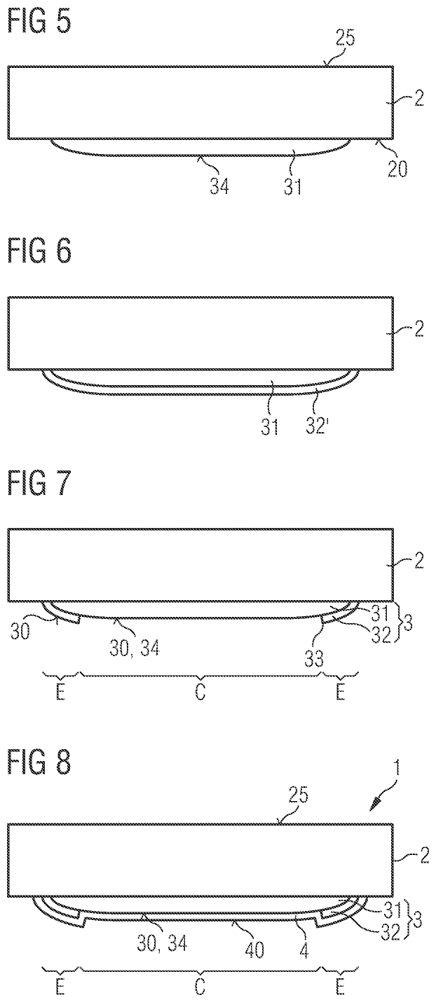

FIGS. 5 to 8 illustrate a further embodiment of the manufacturing process. The steps of FIGS. 5 to 8 are carried out as explained in connection with FIGS. 1 to 4.

Unlike FIGS. 1 to 4, however, the base body 31 is significantly wider in the direction parallel to the bottom side 20. Thus, the valley side 34 in the central region C is flat and is oriented parallel to the bottom side 20; this applies, for example, to at least 70% or to at least 85% of an area of the central region C. In the edge region E, on the other hand, the valley side 34 is curved, as is the bottom side 30.

As in FIG. 4, according to FIG. 8 the entire valley side 34 in the central region C is preferably closer to the bottom side 20 than the ridge line 33.

In all other respects, the comments on FIGS. 1 to 4 apply in the same way to FIGS. 5 to 8, and vice versa.

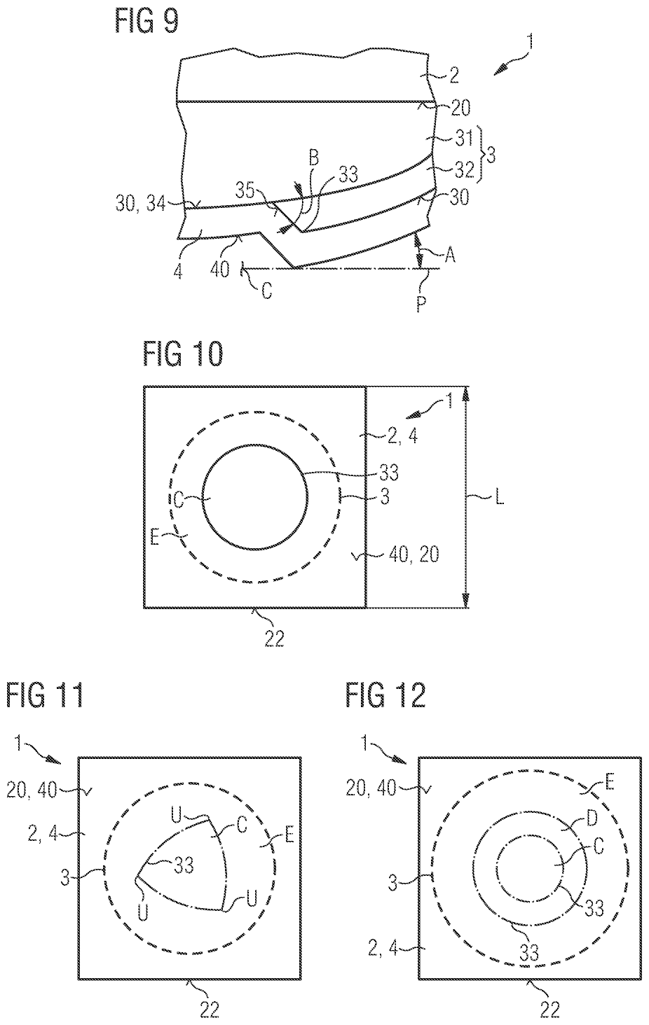

FIG. 9 shows a detailed view of the area around the ridge line 33, such as illustrated in FIG. 4 or 8. In the region of the crest line 33, the contact side 40 preferably has a bend or a rounding with a relatively small radius. Thus, the contact side 40 at the ridge line 33 may be wedge-shaped, as seen in cross-section. In the direction away from the central region C, the contact side 40 preferably has an angle A to a contact plane P. The contact plane P is defined by the ridge line 33 and runs through points of the contact side 40 furthest away from the semiconductor layer sequence 2.

The contact plane P is oriented parallel to the bottom side 20, for example with a tolerance of at most 1.5° or of at most 0.5° or of at most 0.2°. The angle A is preferably more than 0°, for example at least 0.3° or at least 1.2° and/or at most 6° or at most 4°. This preferably also applies to all other embodiments.

Optionally, the step layer 32 has a front side 35 which runs at an angle to the valley side 35, for example with an angle B of at least 45° and/or of at most 80°, in particular between 50° and 70° inclusive. That is, the front side 35 is then not oriented perpendicular to the valley side 34. This facilitates over-shaping of the ridge line 33 and the front side 35 by the electrode layer 4, since excessive slopes of the underside 30 can be avoided.

In all other respects, the comments on FIGS. 1 to 8 apply in the same way to FIG. 9, and vice versa.

In FIGS. 10 to 13, various top views of the bottom sides 20 of semiconductor chips 1 are shown. These semiconductor chips 1 are manufactured in particular by the processes of FIGS. 1 to 4 or 5 to 8.

According to FIG. 10, the exact one ridge line 33 is formed by a closed line, in particular a closed circular line. Thus the central region C is a circular area. A diameter of the central region C is, for example, at least 30% and/or at most 70% of a shortest edge length L of the bottom side 20. Thus a stable support surface for the semiconductor chip 1 can be achieved by the ridge line 33.

The bottom coating 3 can also be circular in shape. A difference in the diameters of the central region C and the edge region E is, for example, at least 5% or at least 10% and/or at most 20% or at most 10% of the shortest edge length L.

Furthermore, it is illustrated in FIG. 10 that the entire bottom side 20 may be covered by the electrode layer 4. That is, the electrode layer 4 may extend to the edge 22 of the bottom side 20. Alternatively, the electrode layer 4 ends at a distance from the edge 22.

In all other respects, the comments on FIGS. 1 to 9 apply in the same way to FIG. 10, and vice versa.

In the example shown in FIG. 11, the ridge line 33 is designed as a closed are triangle, with individual circular arcs meeting at contact points U and being convex in shape. This design of the ridge line makes it possible to have exactly three contact points U, so that the contact plane P can be clearly defined. The bottom coating 3 is again circular and/or spherical segment-shaped, for example.

Deviating from FIG. 11, not only triangles or are triangles, but also polygons or are polygons can be used. For example, in a hexagon or floor hexagon, six of the contact points U may be present, not drawn.

In all other respects, the comments on FIG. 10 apply in the same way to FIG. 11.

FIG. 12 illustrates that there are two ridge lines 33, which are separated from each other by an intermediate region D and which are circled by the common edge region E. The ridge lines 33 may be concentric. The ridge lines 33 can be arranged concentrically. In the intermediate region D, the contact side 40 is closer to the bottom side 20 than in the ridge lines 33.

Deviating from the illustration in FIG. 12, it is also possible that differently shaped ridge lines are combined with each other, for example a circular ridge line with a hexagonal or are hexagonal ridge line.

In all other respects, the comments on FIGS. 10 and 11 apply in the same way to FIG. 12.

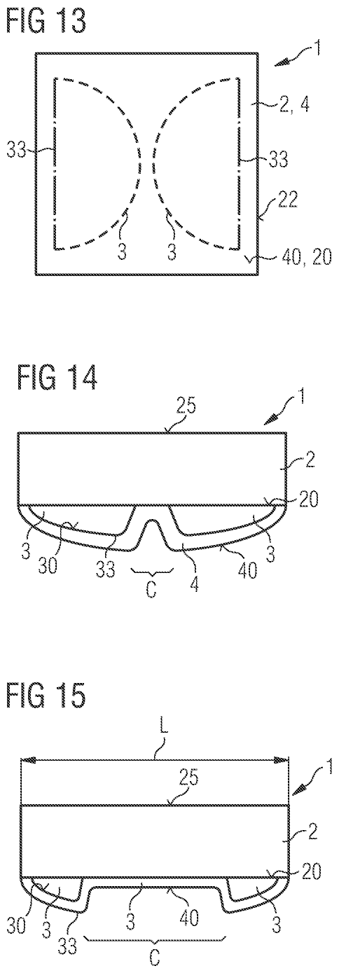

In the embodiment example of FIG. 13, there are also several ridge lines 33. In this case, the ridge lines 33 are straight sections that run parallel to one another, for example. Each of the ridge lines 33 can be assigned its own bottom coating 3. The bottom coatings 3 are configured, for example, in a semicircular shape. In this configuration, the bottom coatings 3 may increase towards the edges 22 associated with the respective ridge lines 33, i.e. have a thickness increasing towards the respective edge 22.

In all other respects, the comments on FIGS. 10 to 12 apply in the same way to FIG. 13.

The top views of FIGS. 10 to 13 can be used for all the sectional views shown.

In the embodiment shown in FIG. 14, the bottom coating 3 is in one piece and circular in shape. The central region C is free of the bottom coating 3, i.e. in the central region C the electrode layer 4 extends directly to the bottom side 20.

In all other respects, the comments on FIGS. 1 to 13 apply in the same way to FIG. 14, and vice versa.

According to FIG. 15, the bottom coating 3 is triangular in shape when viewed in cross-section. This means that, at least in the edge region E, the underside 30 can be in the form of straight sections.

Optionally, the electrode layer 4 is flattened in the region of the ridge line 33. Such a flattened region of the contact side 40 may also be present in all other embodiments. For example, the flattened region, as seen in cross-section through a center of the bottom side 20, has a width of at least 1% or of at most 5% of the minimum edge length L.

In all other respects, the comments on FIG. 14 apply in the same way to FIG. 15.

Based on FIGS. 14 and 15, it is possible that the bottom coating 3 also has a multilayer structure, but that the base body already defines the ridge line by structuring, which then extends through the following, optional layers of the bottom coating 3 to the contact side 40.

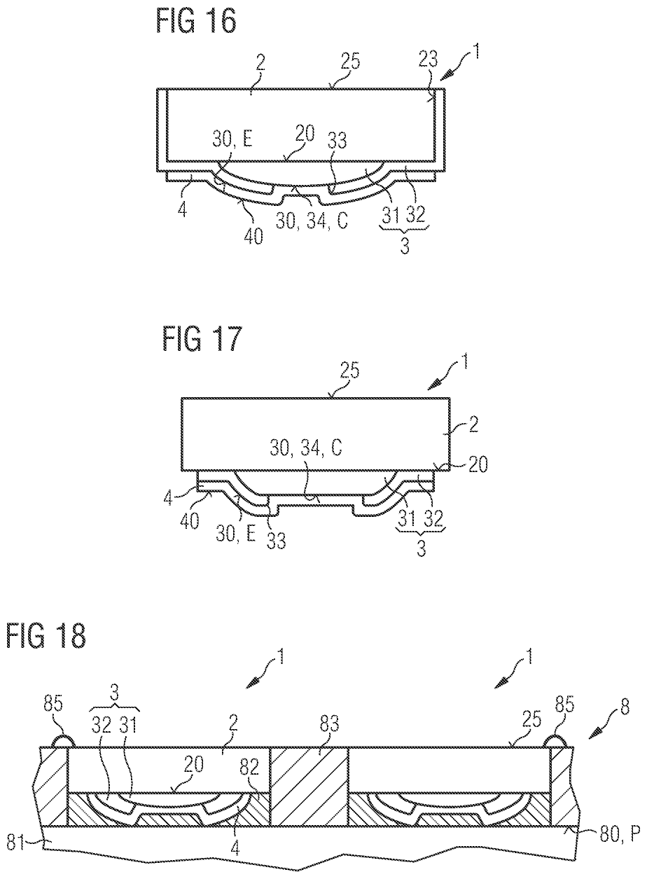

In FIG. 16, it is shown that the step layer 32 of the bottom coating 3 may extend beyond the edge 22 to the side surfaces of the semiconductor layer sequence 2. In this case, the step layer 32 can serve as a passivation of the semiconductor layer sequence 2.

In contrast, the step layer 32 in FIG. 17 already ends at a distance from the edge 22. The step layer 32 and the electrode layer 4 can end equidistant from the edge 22, so that the bottom coating 3 and the electrode layer 4 can be congruent with each other.

In all other respects, the comments on FIGS. 1 to 15 apply in the same way to FIGS. 16 and 17, and vice versa.

In FIG. 18, an embodiment of a semiconductor component 8 is shown. The semiconductor component 8 comprises a plurality of the semiconductor chips 1 as described in connection with FIGS. 1 to 17.

The semiconductor chips 1 are mounted on a common carrier 81, the carrier 81 having a planar carrier mounting side 80 for this purpose. Conductor tracks and electrical connection areas can be located on the carrier mounting side 80, not shown.

The semiconductor chips 1 are attached to the carrier mounting side 80 by means of a mechanical connecting means 82. The connecting means 82 is, for example, an electrically non-conductive adhesive such as a photoresist. The semiconductor chips 1 are mounted, for example, by pressing them onto the carrier 81 through the connecting means 82. This is facilitated by the relatively sharp edges of the contact sides 40 in the region of the ridge lines 33. In addition, defined contact surfaces are ensured by the ridge lines 33.

By shrinking the connecting means 82 during a curing process, it is additionally possible for the semiconductor chips 1 to be attracted to the carrier 81. The ridge lines 33 ensure that an alignment of the semiconductor chips 1 with defined emission directions is maintained even in the case of such shrinkage or shrinkage.

For example, red-green-blue pixels, also known as RGB pixels, are formed by the semiconductor chips 1. That is, red, green and blue emitting semiconductor chips 1 can be combined with each other. The corresponding emission color comes about, for example, directly by the respective semiconductor layer sequence 2 or by means of a phosphor, not shown.

Optionally, a filler material 83 is located between adjacent semiconductor chips 2. The filler material 83 is, for example, white to ensure high radiation efficiency or black to achieve high contrast. Further cover layers can be applied to all semiconductor chips 1 and to the optional filler material 83, not drawn, for example to protect the semiconductor chips 1 mechanically, electrically and/or chemically.

The semiconductor chips 1 are, for example, chips to be contacted on both sides. That is, the emission sides 25 can be electrically connected by means of electrical connection means 85, such as bonding wires. Alternatively, the semiconductor chips 1 may be designed as flip chips. The same applies to all other embodiments.

The components shown in the figures preferably follow one another in the sequence indicated, in particular directly one after the other, unless otherwise described. Components not touching each other in the figures are preferably spaced apart. Insofar as lines are drawn parallel to one another, the associated surfaces are preferably likewise aligned parallel to one another. Furthermore, the relative positions of the drawn components to each other are correctly reproduced in the figures, unless otherwise specified.

The invention described herein is not limited by the description based on the embodiments. Rather, the invention encompasses any new feature as well as any combination of features, which in particular includes any combination of features in the patent claims, even if this feature or combination itself is not explicitly stated in the patent claims or embodiments.

1.-16. (canceled)

17. An optoelectronic semiconductor chip comprising:
a semiconductor layer sequence with a bottom side;
a bottom coating located on the bottom side; and
an electrode layer located on an underside of the bottom coating facing away from the semiconductor layer sequence,
wherein the bottom coating has a thickness gradient and at least one ridge line at which the bottom coating is thickest,
wherein the electrode layer extends over the at least one ridge line such that a contact side of the electrode layer facing away from the semiconductor layer sequence follows the bottom coating true to shape, and
wherein an electrical and mechanical contact plane of the contact side parallel to the bottom side is defined by the at least one ridge line.

18. The optoelectronic semiconductor chip according to claim 17,
wherein the bottom coating comprises exactly one ridge line, and
wherein the ridge line is a closed line.

19. The optoelectronic semiconductor chip according to claim 18, wherein the electrode layer comprises a constant thickness at least within the ridge line.

20. The optoelectronic semiconductor chip according to claim 17, wherein the ridge line or at least one of the ridge lines is a circle, as seen in plan view of the bottom side.

21. The optoelectronic semiconductor chip according to claim 17,
wherein the bottom coating comprises a base body directly located on the bottom side and a step layer on a valley side of the base body facing away from the semiconductor layer sequence,
wherein the valley side is free of the step layer in a central region, and
wherein the step layer runs around the central region.

22. The optoelectronic semiconductor chip according to claim 21, wherein the ridge line or at least one of the ridge lines limits the central region, and wherein a corresponding at least one ridge line protrudes the central region in a direction away from the semiconductor layer sequence.

23. The optoelectronic semiconductor chip according to claim 21, wherein the base body is of an electrically conductive material and the step layer is of a dielectric material.

24. The optoelectronic semiconductor chip according to claim 21,
wherein the step layer comprises a uniform, constant layer thickness in regions where it is present, and
wherein the layer thickness of the step layer is between 20 nm and 0.5 μm, inclusively.

25. The optoelectronic semiconductor chip according to claim 21, wherein the base body is convexly curved throughout such that the base body comprises a collective lens shape when viewed in cross-section.

26. The optoelectronic semiconductor chip according to claim 17, wherein the bottom coating, when viewed in cross section, is curved only in an edge region and is otherwise oriented parallel to the bottom side.

27. The optoelectronic semiconductor chip according to claim 17, wherein the electrode layer completely covers the bottom coating.

28. The optoelectronic semiconductor chip according to claim 17,
wherein the bottom coating comprises a maximum thickness between 50 nm and 0.5 μm, inclusively, and
wherein the semiconductor chip is a μLED such that an edge length of the bottom side, when seen in plan view, is between 1 μm and 30 μm, inclusively.

29. The optoelectronic semiconductor chip according to claim 17, wherein the bottom coating comprises a decreasing thickness starting from the at least one ridge line towards edges of the bottom side.

30. A method for manufacturing the optoelectronic semiconductor chip according to claim 17, the method comprising:
providing the semiconductor layer sequence;
applying the bottom coating to the bottom side;
forming the at least one ridge line; and
providing the electrode layer by overmolding the bottom coating true to shape with a material of the electrode layer.

31. A semiconductor component comprising:
a plurality of optoelectronic semiconductor chips according to claim 17;
a carrier; and
connectors,
wherein the optoelectronic semiconductor chips are fixed to a carrier mounting side of the carrier by the connectors,
wherein the bottom sides are oriented parallel to the carrier mounting side, and
wherein the electrode layers are pressed in a region of the ridge lines by the connectors until the carrier mounting side such that the bottom sides are oriented parallel to one another by the ridge lines.

32. The semiconductor component according to claim 31, wherein the semiconductor component is a red-green-blue display.
